(19) United States
(12) Patent Application Publication
(10) Pub. No.: US 2012/0031469 A1
(43) Pub. Date: Feb. 9, 2012

(54) SUPPORT FOR MOUNTING A SOLAR PANEL

(75) Inventors: Geerling Loois, Boxtel (NL); Stefan Zschoch, Berlin (DE); Michael Kübsch, Bernau bei Berlin (DE)

(73) Assignee: RENUSOL GMBH, Köln (DE)

(21) Appl. No.: 13/128,461

(22) PCT Filed: Nov. 10, 2009
(86) PCT No.: PCT/EP2009/008019

§ 371 Date: Oct. 19, 2011

(30) Foreign Application Priority Data
Nov. 11, 2008 (EP) 08019706.4

(51) Int. Cl. H01L 31/048; F16B 2/06; E04D 13/18; H01L 23/13

(52) U.S. Cl. 136/251; 248/205.1; 248/229.2; 248/222.14; 52/173.3

(57) ABSTRACT

The invention relates to a support (1) for mounting a solar panel (S), having a bottom part (10) for placement on a substantially flat underlying surface, particularly on a roof; a plurality of walls (20) which extend upwards from the bottom part (10), a plurality of supporting surfaces (26, 28) for laying on the solar panel (S) being provided at the upper sides opposite the bottom part; and fastening means (33, 40) for fastening the solar panel on the supporting surfaces, the fastening means clamping the solar panel (S) against the supporting surfaces (26, 28). Preferably, the fastening means (33, 40) comprise at least one clamping rail (40) which is fitted on a lateral border of the solar panel (S) lying on the supporting surfaces (26, 28), and extends continuously over at least half, preferably at least three-quarters, of the longitudinal dimension of the lateral border of the solar panel. Preferably, the support has a stiffener (60) which is insertable between the walls (20) and provides an additional supporting surface (61) for the solar panel (S). The stiffener (60) may be formed as a strut and the walls (20) of the support (1) may have means for mounting the strut.

### BACKGROUND OF THE DISCLOSURE

The invention relates to a support for supporting or mounting a solar panel on a roof, such as, for example, a flat roof. In addition, the invention relates to an arrangement consisting of such a support and a solar panel mounted thereon.

European patent publication EP 0 857 926 A1 describes an example of a known support for a solar panel. This support has a trough-shaped or box-shaped structure with a flat upper border which serves as a supporting surface for the solar panel. In this case, the solar panels have a frame made of aluminum which extends around the periphery of the panel. The solar panel is fastened to this frame at the upper and lower border of the support by means of screws.

The new generation of solar panels are, however, lighter, thinner modules produced without metal frames. The object underlying the invention is therefore to provide a new support for solar panels, in particular for thin-layer, frameless solar panels, with which a solar panel can be positioned in a simple manner and reliably and securely fastened.

### SUMMARY OF THE INVENTION

This object is achieved by a support according to claim 1 or claim 14. According to the invention, an arrangement consisting of such a support and a solar panel is provided. Preferred embodiments of the invention emerge from the features of the dependent claims.

In one aspect, a support according to the invention for supporting or mounting a solar panel has the following features:

a bottom part for placement on an underlying surface, particularly on a roof, such as, for example, a flat roof,

a plurality of walls which extend upwards from the bottom part, a supporting surface for laying on the solar panel being provided on each of the upper sides of the walls opposite the bottom part, and

fastening means for fastening the solar panel on the supporting surfaces, the fastening means clamping the solar panel against the supporting surfaces.

Preferably, the clamping takes place over at least half, and preferably at least ¾, of a longitudinal dimension of a lateral border of the solar panel lying on the supporting surfaces.

In a preferred form of the invention, the fastening means comprise at least one clamping rail which is fitted on a lateral border of the solar panel lying on the supporting surfaces, and extends (preferably continuously) over at least half of the longitudinal dimension of the lateral border of the solar panel. With further preference, the fastening means comprise at least two clamping rails which extend continuously over at least half of the longitudinal dimension of two opposite lateral borders of the solar panel.

In a preferred form of the invention, the supporting surfaces extend substantially in one plane and continuously over at least half, preferably at least ¾ and more preferably the whole, of the longitudinal dimension of a lateral border, preferably of two opposite lateral borders of the solar panel.

Since the new solar panels are comparatively thin (e.g. with a wall thickness in the range of 6 to 7 mm) and consist of glass layers which have only limited flexibility, are relatively light and therefore sensitive, it is important to fasten such solar panels as reliably and securely as possible. In order to achieve this, the inventors have found that the lateral borders of the panel should lie flat, ideally continuously over more than half of their lengths, on the supporting surfaces and be clamped thereto. With the mounting system of present invention, it is possible to dispense with a metal frame for the solar panels. The frame of the solar panel is effectively replaced by the clamping rails, which lead not only to a simplified and more cost-effective production of the panels, but also a quicker and more reliable mounting of the panels.

In a preferred form of the invention, each clamping rail has a covering part which is fitted directly on the lateral border of the solar panel, and a fixing part which extends outside a periphery of the solar panel. The walls of the support have an upper border, e.g. in the form of a flange, at their upper sides opposite the bottom part, which border or flange at least partly comprises the supporting surfaces and also supports the clamping rail(s). Preferably, the border or flange runs around the upper periphery of the walls. The upper border or flange preferably extends outside the periphery of the solar panel lying on the supporting surfaces, and the fixing part of the clamping rail(s) is fitted and fixed on the border or flange.

In a preferred form of the invention, the at least one clamping rail is fixed by one or more screw(s). The fastening means additionally comprise attachments or bushes for receiving screws, which attachments or bushes are situated at a lower side of the upper border or flange, and are preferably formed integrally with the border or flange and/or with the walls of the support. If the attachments or bushes are correctly matched to the screws, it is possible for the clamping rails and thus also the solar panel to be fastened on the support by simple screwing in. In other words, a fitter does not need a nut for the screws. The screws cut into the material of the attachments or bushes and thus firmly fix the rail to the respective flange. Preferably, two or three screws per clamping rail are used.

In a preferred form of the invention, the at least one clamping rail has a yielding or elastic element which absorbs the clamping pressure and distributes it over the lateral border of the solar panel. The yielding or elastic element is situated, for example, in the covering part of the at least one clamping rail.

In a preferred form of the invention, the bottom part of the support consists mainly of a bottom with the walls rising at the periphery thereof, so that the bottom and the walls together form a chamber for receiving ballast and preferably provide a trough-shaped or box-shaped structure of the support. By providing ballast, the support or an arrangement consisting of support and solar panel can be weighted down and thus stabilized. The ballast chamber can be filled with loose poured ballast, such as, for instance, gravel which is already present on a roof, or filled with stones in its interior, in order to hold the support in place.

The walls of the support preferably comprise a high rear wall, a low front wall and two lateral walls, which are connected to one another and laterally enclose the chamber. The border or flange runs around the upper periphery of the walls. The different heights of the rear and front walls of the support define a sloping position of the solar panel lying on the supporting surfaces with respect to the bottom or the roof plane. In a preferred form of the invention, the solar panel is at an angle of 10 to 40 degrees with respect to the roof plane. More preferably, the solar panel is at an angle of 10 to 20 degrees with respect to the roof plane. Admittedly, this angle is not optimal for the individual solar panel in Northern Europe, but several supports can thus be placed so closely behind one another, without a mutual shadow effect, that the efficiency is very satisfactory for a fully covered roof. The walls and/or bottom are preferably formed with parallel-running projections or recesses, in order to create a stronger and more stable structure.

In a preferred form of the invention, the support comprises a stiffener insertable between the walls, the walls having means for mounting this stiffener. The stiffener is preferably formed as at least one strut and the means for mounting the stiffener may have recesses or cutouts in the walls for fitting or inserting the strut. This strut is preferably inserted between the rear and front walls and is particularly advantageous in regions where snow is possible. In the event of heavy snowfall, an arrangement consisting of the support and solar panel is often heavily loaded by an accumulation of snow and ice, which may result in deformation or even breakage of the arrangement with conventional supports. An additional stiffener therefore increases the rigidity and thus the stability of the arrangement in regions where winter often brings snow. This stiffener, for example in the form of at least one strut, is preferably inserted underneath the solar panel and may also provide an additional supporting surface for the panel.

In another aspect, the support according to the invention for supporting or mounting a solar panel has the following features:

a bottom part for placement on an underlying surface, in particular on a roof, such as, for example, a flat roof,

a plurality of walls which extend upwards from the bottom part, a supporting surface for laying on the solar panel being provided on each of the upper sides of the walls opposite the bottom part, and

fastening means for fastening the solar panel on the supporting surfaces, the fastening means being suitable for clamping the solar panel against the supporting surfaces.

Preferably, the walls of the support have means for mounting a stiffener insertable between the walls. As already mentioned above, the stiffener is preferably formed as a strut and the mounting means comprise recesses or cutouts in the walls for fitting or inserting the strut.

In a preferred form of the invention, the supporting surfaces comprise at least one lateral surface which supports an edge of the solar panel and serves for positioning the solar panel on the support. Preferably, the support has at least one stop on or at the upper border or flange, which stop comprises the said lateral surface. Preferably, the at least one stop is situated at the upper border or flange of the front wall of the support.

In a preferred form of the invention, the support is formed in such a manner that it can be stacked by nesting on an identical support. Several supports can be transported in a compactly stacked manner if the support is formed so as to be stacked by nesting on a similar or identical support.

### BRIEF DESCRIPTION OF THE DRAWINGS

Further preferred configurations of the invention will emerge from the following description of exemplary embodiments which are given with reference to the attached figures, where components which are functionally identical or functional similar to one another are designated by the same reference symbols. In the drawings:

FIG. 1 shows an isometric front view of a support according to an exemplary embodiment of the invention, without a solar panel;

FIG. 2 shows an isometric rear view of a support according to an exemplary embodiment of the invention, without a solar panel;

FIG. 3 shows an isometric view of the support according to the invention as in FIG. 1;

FIG. 3A shows an isometric view of details of the supporting surfaces and of the fastening means of the region “Z” of the support shown in FIG. 3;

FIG. 3B shows an isometric bottom view in the direction of the arrow “A” of the supporting surfaces and fastening means of the support shown in FIG. 3A;

FIG. 3C shows an isometric view of details of the supporting surfaces and of the fastening means of the region “W” of the support shown in FIG. 3B;

FIG. 3D shows an isometric view of details of the supporting surfaces and of the fastening means of the region “Y” of the support shown in FIG. 3;

FIG. 3E shows an isometric bottom view in the direction of the arrow “B” of the supporting surfaces and fastening means of the support shown in FIG. 3D;

FIG. 4 shows a front detail view of the mounting system of the support shown in FIGS. 1 and 2, with a solar panel;

FIG. 4A shows a top detail view of the mounting system in the direction of the arrow “A” of the support shown in FIG. 4, with a solar panel;

FIG. 5 shows an isometric view of the support according to the invention as in FIG. 1;

FIG. 5A shows an isometric view of details of the border of the front wall of the region “V” of the support shown in FIG. 5;

FIG. 5B shows an isometric rear view in the direction of the arrow “C” of the border of the front wall of the support shown in FIG. 5A;

FIG. 5C shows an isometric view of details of the border of the rear wall of the region “T” of the support shown in FIG. 5;

FIG. 5D shows an isometric rear view in the direction of the arrow “D” of the border of the rear wall of the support shown in FIG. 5C;

FIG. 5E shows an isometric view of details of the border of the rear wall of the region “U” of the support shown in FIG. 5;

FIG. 5F shows an isometric rear view in the direction of the arrow “E” of the border of the rear wall of the support shown in FIG. 5E;

FIG. 6 shows an isometric front view of a support according to an exemplary embodiment of the invention, with a solar panel;

FIG. 7 shows an isometric front view of the support in FIG. 6, without a solar panel;

FIG. 8 shows an isometric view of details of the support in FIG. 6, shown with the solar panel partly cut away;

FIG. 8A shows an isometric view of details of the fastening means of the region “S” of the support shown in FIG. 8; and

FIG. 8B shows an isometric view of details of the fastening means of the region “R” of the support shown in FIG. 8.

### DETAILED DESCRIPTION OF THE EMBODIMENTS

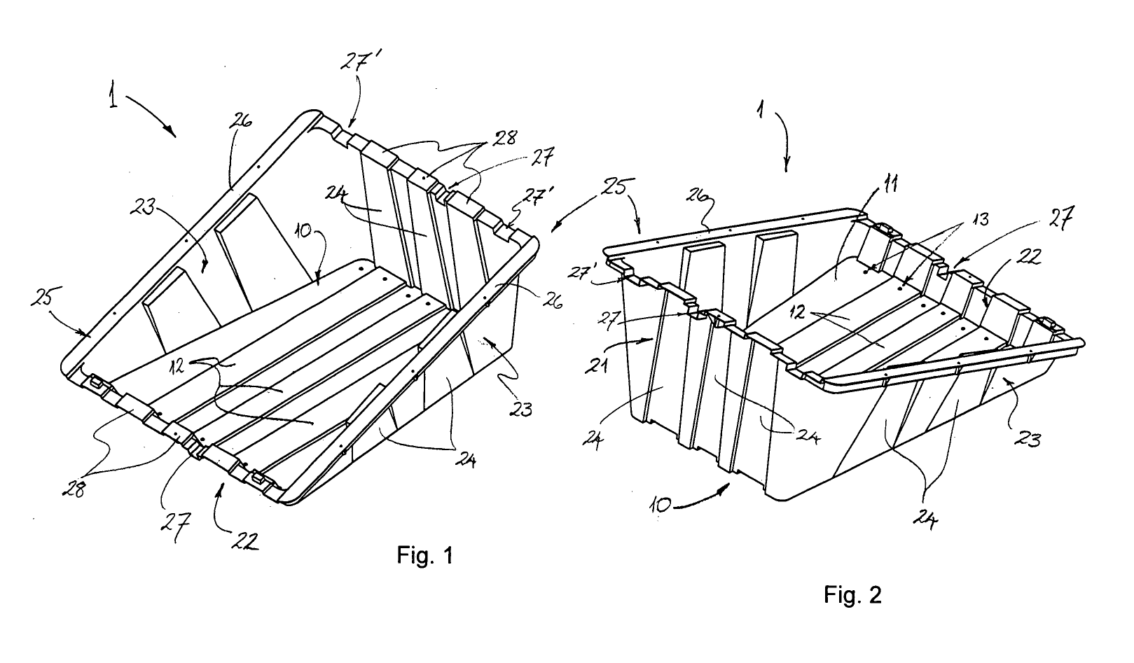

With reference to FIGS. 1 to 4A, a support 1 according to the invention for a solar panel S is illustrated. The support 1 comprises a bottom part 10 for placement of the support on a substantially flat underlying surface, and in particular on a roof. The bottom part 10 consists mainly of a bottom 11 which is formed from a plate and with projections or recesses 12 running parallel. The parallel projections or recesses 12 form a ribbed bottom profile and thus increase the flexural strength and the stability of the bottom 11. Two rows of holes 13 through the bottom plate 11 are provided for the drainage of rainwater or moisture.

Extending around the periphery of the bottom part 10 are four walls 20 which, together with the bottom 11, give the support 1 a trough-shaped or box-shaped structure. The four walls 20 comprise a high rear wall 21, a low front wall 22 and two lateral walls 23, which are connected to one another and, together with the bottom 11, form a chamber 30 for receiving ballast. Like the bottom plate 11, the walls 20 have parallel projections or recesses 24 which, as reinforcing ribs, make the structure and the profile of the support 1 stiffer and more stable. This stability is particularly advantageous if the support 1 is subjected to higher loads of wind and snow.

At an upper side opposite the bottom part 10, the walls 20 are bounded by an upper border 25, which border 25 comprises supporting surfaces for laying on the solar panel S. At each of the two side walls 23, the border 25 is configured in the form of a flange and constitutes a continuously flat supporting surface 26 extending over the entire lateral dimension of the support. At the upper sides of the rear and front walls 21, 22, the border 25 is uneven and not continuously flat, as a result of recesses or cutouts 27, 27′. However, both the upper border 25 of the rear wall 21 and the upper border 25 of the front wall 22 have several supporting surfaces 28, lying in the same plane, for the solar panel S. In other words, the solar panel S is laid on the supporting surfaces 26, 28 and supported by them.

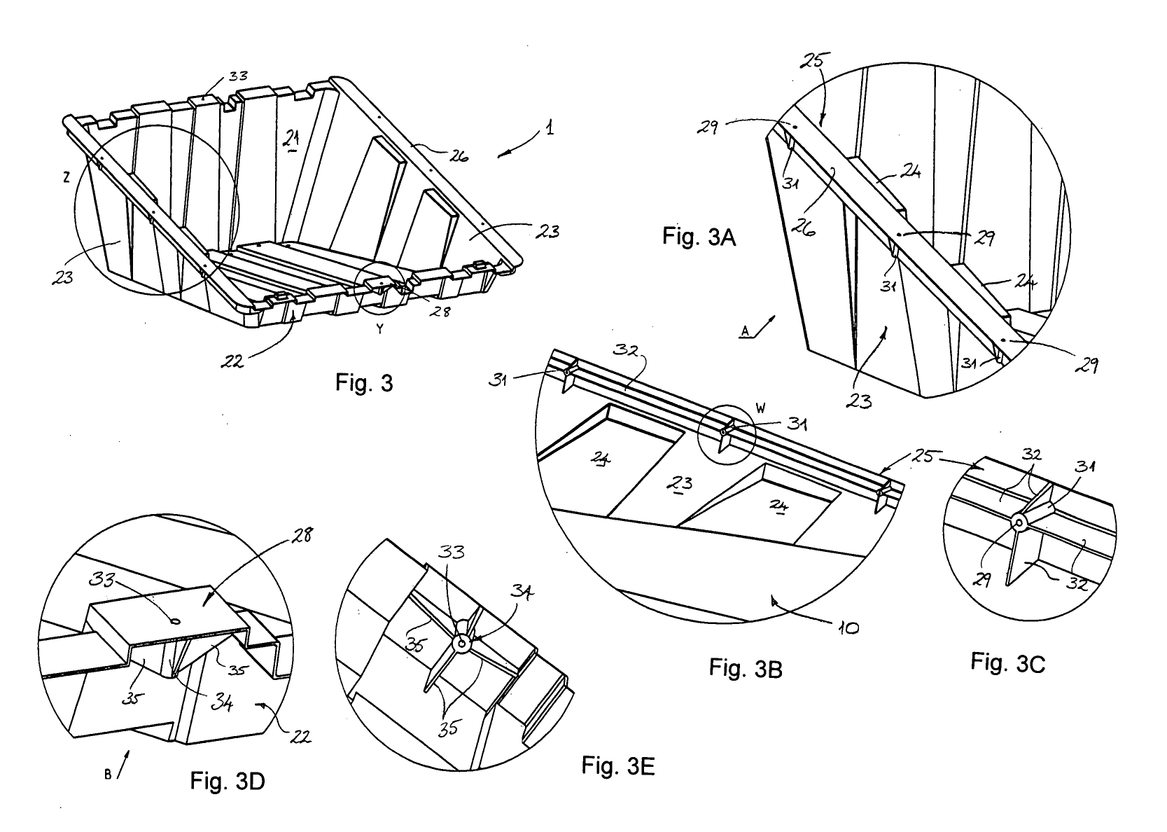

With reference now to FIGS. 3 to 3C, the lateral flanges 25 have a row of fixing holes 29 arranged spaced apart from one another, which serve as fastening means for fastening the solar panel S. Each of these fixing holes 29 extends through the respective flange 25 and an attachment 31 formed underneath the flange 25 and serving as a tubular bush for receiving a screw. The lower side of the flange 25 and thus also the sides of the attachments 31 are provided with reinforcing webs 32, in order to provide a stronger and more stable fastening structure. As can be seen in FIGS. 3D and 3E, the centrally located supporting surfaces 28 of the rear and front walls 21, 22 also have further fixing holes 33 with tubular attachments or bushes 34 which are also formed stably with the upper border 25 of the front and rear walls 21, 22 via reinforcing webs 25.

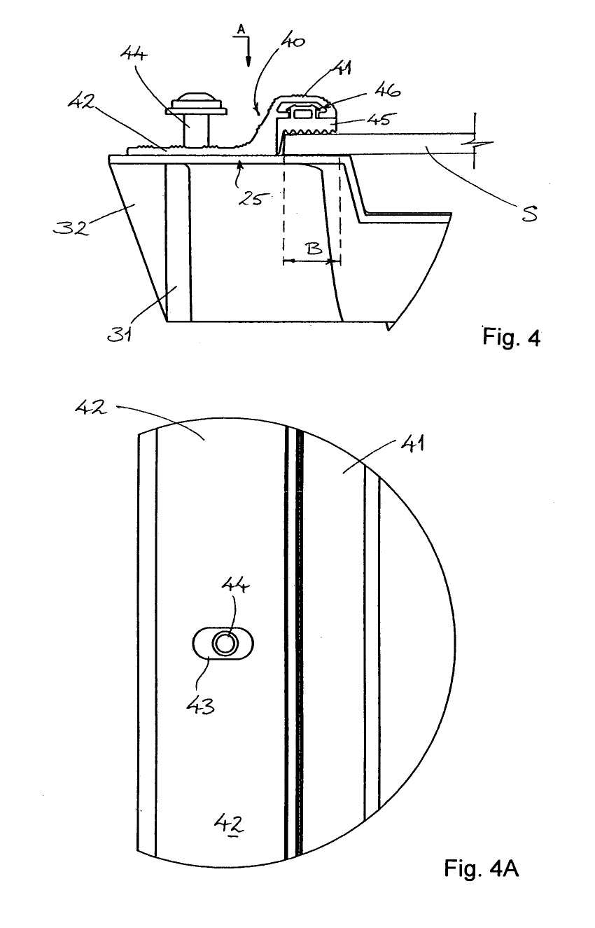

The mounting and fixing of the solar panel S is shown in detail in FIGS. 4 and 4A. The fastening means for fastening the solar panel S on the support 1 have two lateral clamping rails 40 which are suitable for clamping the solar panel against the supporting surfaces 26 of the flange 25. Each clamping rail 40 comprises a covering part 41 which is fitted over a lateral edge on a border region of the solar panel S lying on the supporting surfaces 26, and a fixing part 42 which extends over the flange 25 outside the periphery of the solar panel S. Particularly preferably, the clamping rails 40 stretch continuously over at least half and with further preference at least three-quarters of the longitudinal dimension of the lateral border of the solar panel S against the supporting surfaces 26 of the flanges 25. In this way, the thin-layer module S is stably mounted on the support 1.

The fixing part 42 of the clamping rail 40 is provided with elongated holes 43 which can be aligned with the fixing holes 29 through the flange 25, so that screws 44 can be screwed through the rail 40 into the attachments 31 or bushes, in order to fix the rail 40 and thus the solar panel S in position on the support 1. The elongated holes 43 have a certain play in the lateral direction with respect to the holes 29, in order to allow adjustment and precise positioning of the clamping rails 40. Furthermore, each clamping rail 40 has a yielding element 45 made of a relatively soft, elastic material, such as, for example, rubber or the like, which element 45 is arranged in a recess 46 at a lower side along the covering part 41. The elastic element 45 makes the clamping contact with the upper border region of the solar panel S, absorbs the clamping pressure and distributes it along the lateral edge of the solar panel S lying on the lateral supporting surfaces 26.

The new thin-layer solar panels or modules are rectangular and have a typical size of about 1.1 m×1.3 m. These panels or modules are normally oriented such that the longer sides (of 1.3 m) extend between the rear and front walls 21, 22 of the support and are supported on the lateral borders or flanges 25. The solar cells in the modules are arranged in such a manner that a border region B of the solar panel of about 5 to 15 mm (e.g. 10 mm) does not generate any electricity and is thus ideally suited for fastening by the lateral clamping rails 40. In other words, the covering part 41 of the clamping rail 40 can cover this border region B without problems.

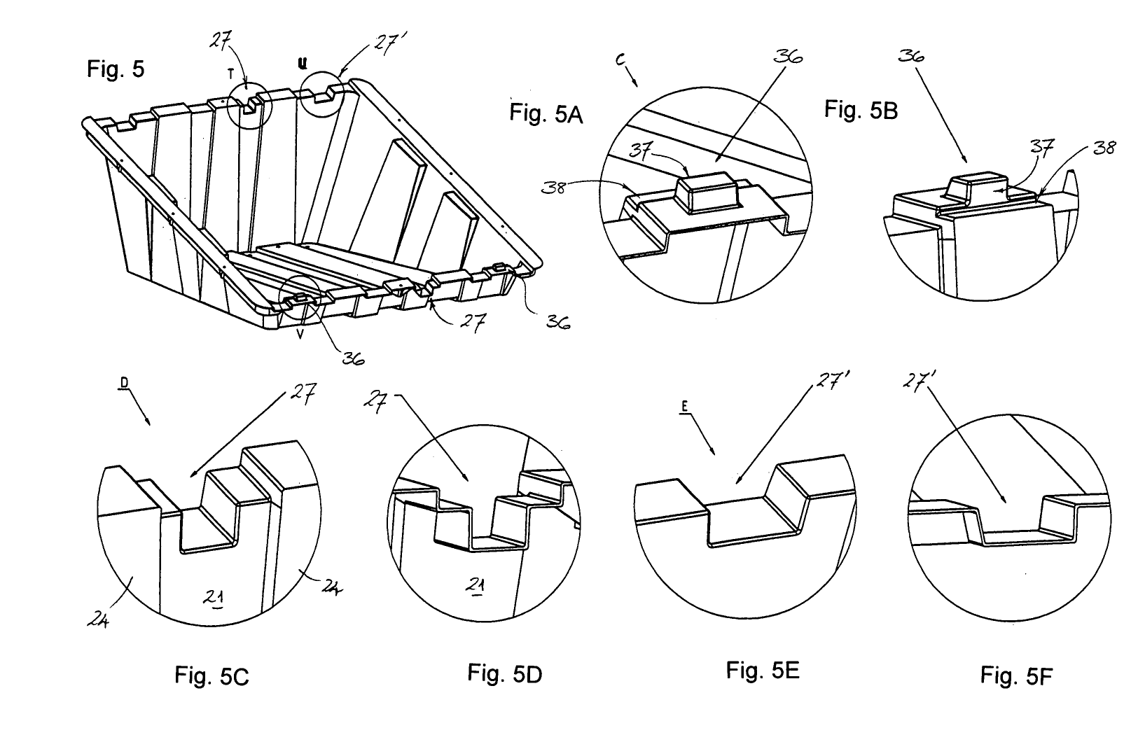

With reference now to FIGS. 5 to 5F, further details of the front and rear walls 21, 22 are illustrated. FIGS. 5A and 5B show, for example, prominences 36 at the left and right sides of the front wall 22. These prominences 36 form stops which serve for stable positioning and mounting of the solar panel S on the support. Each stop 36 has a rear lateral surface 37 and a lower surface 38 which act as further supporting surfaces for the front or lower edge E of the solar panel S. The front or lower edge E of the solar panel S is supported against the lateral surfaces 37 and centred on the support 1, after which the clamping rails 40 can be fastened to the borders of the panel. The lateral surfaces 37 of the stops 36 therefore function as means for preventing the solar panel S from slipping off and the lower surfaces 38 of the stops 36 lie in a plane with the other supporting surfaces 26, 28.

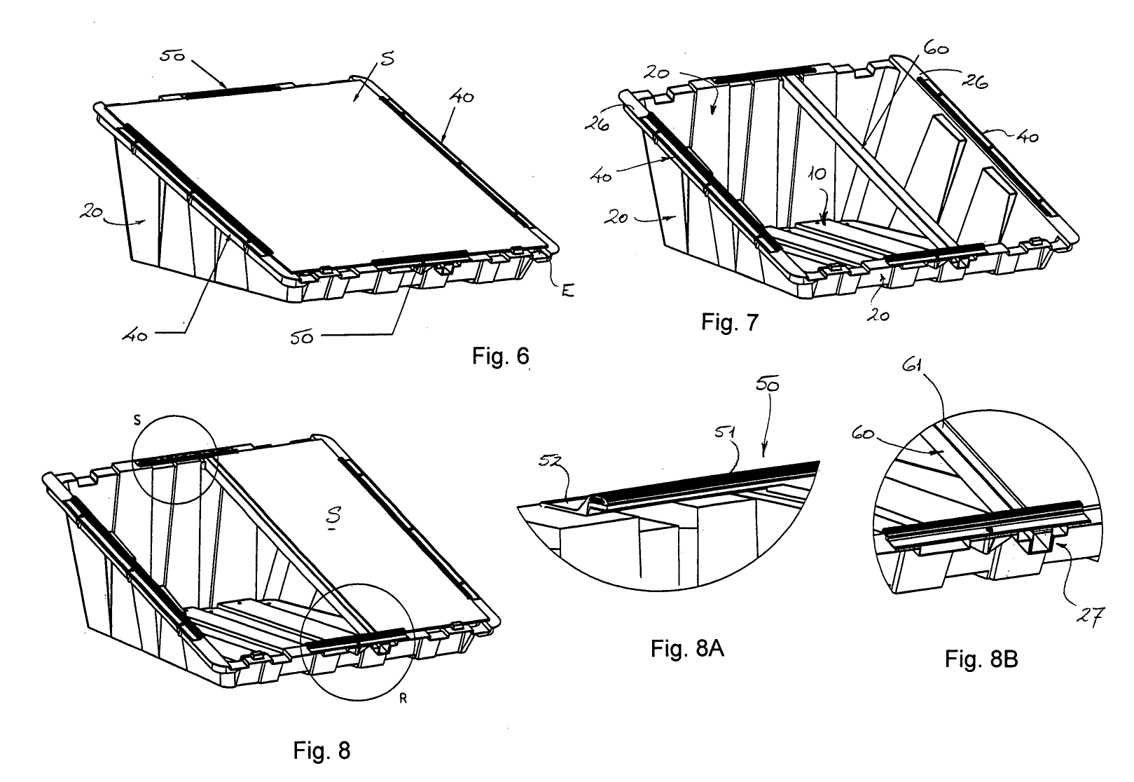

In FIGS. 5C and 5D, one of two opposite cutouts 27 formed in the rear and front walls is shown in a close-up from two directions. Each of these cutouts 27 serves as means for mounting a stiffener of the support; here, each cutout 27 is suitable for receiving a respective end of a stiffening strut (not shown). The strut is received in such a manner in the cutouts 27 that it extends between the front and rear walls 21, 22, and that its upper side forms an additional supporting surface for the solar panel S. The strut brings about a stiffening and reinforcement of the support 1 in the direction between the front and rear walls. Such a strut is shown more clearly in the exemplary embodiment of FIGS. 6 to 8B.

FIGS. 5E and 5F show another recess or notch 27′ in the rear wall 21 of the support. Two such notches 27′ are provided in the rear wall as cable ducts. The cables, which connect the solar cells of the panels or modules to a local electricity consumer or consumer network or to a storage installation, can be led through these notches 27′ and through the chamber 30 of the support 1.

With reference to FIGS. 6 and 7, an arrangement according to the invention is shown, consisting of a support 1 according to the invention and a solar panel S mounted thereon. The lateral clamping rails 40 can be clearly seen. In this exemplary embodiment, however, there are further clamping rails 50 fixed to the upper border 25 of the front and rear walls 21, 22. These further clamping rails 50 are shown in a close-up in FIGS. 8 to 8B. The form or construction of the clamping rails 50 corresponds to that of the lateral clamping rails 40 shown in FIGS. 4 and 4A and they are fixed to the rear and front border of the support and of the panel. The hole 33 and the corresponding attachment 34, which are shown in FIGS. 3D and 3E, may be suitable, for example, for this purpose. These additional rails 50 function as a wind suction safeguard against the suction force of a wind which is incident, for example, from the north and blows from the rear over the support and the solar panel mounted thereon. In this connection, it should be noted that in the northern hemisphere the high side of the support 1 is always to be directed to the north, in order to orientate the solar panel to the sun. The chamber 30 of the box-shaped support 1 is filled with ballast, in order to hold it in place. The ballast may, for example, be gravel which originally lay at the location of the support, or paving stones which are supplied for this purpose. Since the solar panel S is relatively thin, the suction force of the wind blowing over the support could be strong enough to severely bend a panel not fastened at its upper border or even tear it from the support. The upper and lower clamping rails 50 therefore serve as a safeguard for the solar panel S against such wind suction.

In FIGS. 7 and 8, a stiffening strut 60 running between the front and rear walls 21, 22 can also be clearly seen. The respective ends of this strut 60 are inserted in the opposite cutouts 27 and the upper side 61 forms an additional supporting surface for the solar panel S. The strut 60 brings about a stiffening and reinforcement of the support 1, which considerably improves the loadability of the support in the event of snow.

The inclination of the walls 20 of the support 1 which project upwards from the bottom 11 is set such that the support 1 is self-releasing from the mould after the vacuum thermoforming or injection-compression molding. This shape enables several supports 1 to be nested in the vertical direction, resulting in a compact stack which is easy to transport. This nestable shape of the support is particularly important, since a relatively large number of supports and solar panels are typically installed on a single roof, for example in directly juxtaposed rows which completely cover a large part of the roof surface.

The support according to the invention is preferably produced from a plastic, such as, for example, polyurethane, polyethylene or the like, in an injection-compression molding process, although vacuum thermoforming of the support is also possible.

The purpose of the above description is to illustrate the mode of operation of preferred embodiments of the invention, and not limit the scope of the invention. Proceeding from the above explanation, many variations which are encompassed by the disclosure content of the present invention will be obvious to a person skilled in the art.

1. A support for mounting a solar panel, the support comprising:
a bottom part for placement on a substantially flat underlying surface,
a plurality of walls, which extend upwards from the bottom part, so that the bottom part and the walls form a chamber for receiving ballast and configure the support with a trough-shaped or box-shaped structure, supporting surfaces for laying on the solar panel being provided at the upper sides of the walls opposite the bottom part, and
fastening means for fastening the solar panel on the supporting surfaces, the fastening means being suitable or designed for clamping the solar panel against the supporting surfaces.

2. The support of claim 1, the fastening means comprising at least one clamping rail, which is fitted in such a manner on a lateral border of the solar panel lying on the supporting surfaces that it clamps the solar panel against the supporting surfaces.

3. The support of claim 2, the at least one clamping rail extending continuously over at least half of the longitudinal dimension of the lateral border of the solar panel.

4. The support of claim 2, the fastening means comprising at least two clamping rails which are fitted on two opposite lateral borders of the solar panel.

5. The support of claim 3, the at least one clamping rail having a covering part which is fitted directly over the lateral border of the solar panel, and a fixing part which extends outside a periphery of the solar panel.

6. The support of claim 1, the walls of the support having a border or flange at their upper sides opposite the bottom part, which border or flange comprises the supporting surfaces and supports the at least one clamping rail or the fixing part thereof.

7. The support of claim 6, the border or flange extending outside the periphery of the solar panel lying on the supporting surfaces, and the fixing part of the at least one clamping rail being fitted and fixed on the border or flange.

8. The support of claim 1, the fastening means comprising attachments or bushes for receiving screws, which attachments or bushes are situated at a lower side of the border or flange, and are preferably formed integrally with the border or flange and/or with the walls.

9. The support of claim 5, the covering part having a width in the range from 5 mm to 15 mm, preferably from 8 mm to 12 mm, and the fixing part having a width in the range from 10 mm to 25 mm, preferably 15 mm to 20 mm.

10. The support of claim 2, the at least one clamping rail comprising a yielding or elastic element which absorbs the clamping pressure and distributes it over the lateral border of the solar panel, the yielding or elastic element preferably being situated in the covering part of the at least one clamping rail, and the yielding or elastic element preferably having an elongated form and extending along the clamping rails.

11. The support of claim 1, further comprising a stiffener, which is insertable between the walls (20) of the support and provides an additional supporting surface for the solar panel.

12. The support of claim 11, the walls having means for mounting the stiffener, the mounting means comprising recesses or cutouts in the walls for fitting or inserting the strut.

13. The support of claim 1, the supporting surfaces comprising at least one lateral surface which supports an edge of the solar panel and serves for positioning the solar panel on the support, and at least one stop being formed on or at the border or flange, and the stop comprising the lateral surface.

14. A support for mounting a solar panel comprising
a bottom part for placement on a substantially flat underlying surface, particularly on a roof,
a plurality of walls, which extend upwards from the bottom part, so that the bottom part and the walls form a chamber for receiving ballast and configure the support with a trough-shaped or box-shaped structure,
a border or flange at the upper sides of the walls opposite the bottom part, the border or flange comprising supporting surfaces for laying on the solar panel, and
fastening means for fastening the solar panel on the supporting surfaces, the fastening means comprising at least one clamping rail, which is fitted on the border or flange over a lateral border of the solar panel lying on the supporting surfaces and which clamps the solar panel against the supporting surfaces.

15. The support of claim 14, each clamping rail having a covering part which is fitted directly over the lateral border of the solar panel and a fixing part which is supported by the border or flange.

16. The support of claim 15, the fixing part of the at least one clamping rail being fitted and fixed on the border or flange outside a periphery of the solar panel lying on the supporting surfaces.

17. The support of claim 14, further comprising a stiffener which is insertable between the walls of the support and provides an additional supporting surface for the solar panel.

18. The support of claim 14, the support being formed in such a manner that it is suitable for nesting with a similar or identical support.

19. The support of claim 14, the support being produced substantially from a plastic, such as, for example, polyurethane, polyethylene, preferably by an injection-compression molding process or vacuum thermoforming.

20. A device comprising a support according to claim 1 and a solar panel.
